(19) United States
(12) Patent Application Publication
(10) Pub. No.: US 2025/0150074 A1
(43) Pub. Date: May 8, 2025

(54) SIGNAL OUTPUT COMPONENT FOR CONTROLLING A GATE DRIVER FOR A POWER ELECTRONICS SYSTEM

(71) Applicant: ZF Friedrichshafen AG, Friedrichshafen (DE)

(72) Inventors: Michael Sperber, Bayreuth (DE); Michael Meiler, Bayreuth (DE); Danil Hudenkov, Speichersdorf (DE)

(73) Assignee: ZF Friedrichshafen AG, Friedrichshafen (DE)

(21) Appl. No.: 18/837,448

(22) PCT Filed: Feb. 10, 2023
(86) PCT No.: PCT/EP2023/053279

§ 371 Date: Aug. 9, 2024

(30) Foreign Application Priority Data
Feb. 11, 2022 (DE) 10 2022 201 439.1

(51) Int. Cl. H03K 17/687; B60L 15/00; H02M 1/088; H02M 7/5395; H03K 17/567

(52) U.S. Cl. CPC H03K 17/687; B60L 15/007; H02M 1/088; H02M 7/5395; H03K 17/567

(57) ABSTRACT

A gate driver component for controlling at least two power semiconductors that form a topological switch and are made of different semiconductor materials and/or types.

The present invention relates to the field of electric mobility, in particular a signal output component for controlling a gate driver.

Semiconductor transistors are used in many fields as electronic switches, also referred to as semiconductor switches. This is possible because a semiconductor switch can switch back and forth between two states. The first of these is when it is switched on. In this state, the semiconductor switch can conduct electricity, and behaves like a low resistor or a diode in the direction in which the electricity is conducted. In the other state, it is switched off. In this state, the semiconductor can absorb voltages of 400 V or 800 V.

A semiconductor switch switches between the two states quickly and efficiently. This switching on and off is the basis for many electronic circuits such as power supplies, converters, rectifiers, and inverters.

For the semiconductor switch to be able to switch back and forth between these two states, it has a control connection, the so-called gate driver, with which the semiconductor switch is controlled. There are two basic types of semiconductor switches. These are semiconductor switches controlled with voltage, and semiconductor switches controlled with amperage. With the voltage-controlled semiconductor switches, the control voltage must be above or below a defined level, e.g. +5 V or −3 V, in order to switch the state of the semiconductor switch (on or off). With amperage-controlled semiconductor switches, the amperage must be above or below a defined control amperage to switch between the two states. A control circuit is needed to control both types of semiconductor switches.

Existing control circuits or assemblies (gate drivers) have and input and an output. The input has at least one signal value containing information regarding whether the semiconductor switch is to be switched on (conductive state) or off (non-conductive state). Furthermore, the potentials can be separated between the input and output. The output has at least one output signal, which indicates the voltage level, amperage, etc. to the control assembly such that the semiconductor switch can be controlled directly with this signal.

The applicant has already proposed an assembly for a topological switch that contains at least two power semiconductors, in particular power transistors, the topological semiconductor switch of which has at least one first power semiconductor containing a first semiconductor material, and at least one second power semiconductor, containing a second semiconductor material.

Most of the control assemblies described above can only be used with topological semiconductor switches made of the same types of semiconductor switches. With a topological switch made of a parallel connection of different semiconductor materials such as Si, SiC, GaN, etc., and/or different types of semiconductors such as MOSFETs (metal-oxide-semiconductor field-effect transistors), IGBTs (insulated-gate bipolar transistors), JFETs (junction field-effect transistors), etc., it is not possible to control the different types of semiconductors separately with this assembly, because each type of semiconductor switch requires a separate control signal.

The object of the invention is to overcome this problem. This is achieved by the features of the independent claims. Advantageous embodiments are the subject matter of the dependent claims.

The invention makes use of a signal output component for controlling at least one gate driver with which at least two power semiconductors are controlled, which form a topological switch and are made of different semiconductor materials and/or types. The signal output component has an output for each power semiconductor, and a unit for generating a control matrix that outputs at least one output signal to at least one output. It also has a first input, which has a predefined input signal that is sent directly to the unit for generating a control matrix, and a second input containing a state variable or a state variable vector that is sent to a converter. The state variable or state variable vector is converted in the converter to a computing value that is sent directly to the unit for generating a control matrix. The state variable or state variable vector is also converted to a logical value indicating which of the power semiconductors is to be switched on, which is then sent directly to the unit for generating a control matrix. There is also a parameter selector to which the logical value is sent. The parameter selector determines the dead time and modulation frequency parameters needed to control the gate driver, and sends them to the unit for generating a control matrix. A degree of modulation is calculated in the unit for generating a control matrix from the input signal and the computing value, and the logical value, dead time, and modulation frequency are linked to one another. At least one output control signal is determined from this (the input values in the unit for generating a control matrix), which is output to the at least one gate driver.

The switching speed depends on which semiconductor materials and/or types are used, i.e. the control patterns for the low-side switch and high-side switch in the topological switch may differ with respect to their dead time and control frequency. Different power semiconductors can be controlled based on their states and in an optimal manner with the proposed signal output component by providing different control patterns for each output, without the need for additional hardware. By obtaining the output signal upstream of the gate driver, i.e. in a microcontroller, the amount of hardware can be reduced, because only one microcontroller is needed for controlling numerous gate drivers.

In one embodiment, the first output is configured to control the first power semiconductor with a first dead time TD.1 and a first modulation frequency fm.1, and each of the other outputs are configured to control each of the other power semiconductors with another dead time TD.n+1 and another modulation frequency fm.n+1, in which: TD.n+1≥TD.n and fm.n+1≤fm.n, where n is the number of outputs.

In one embodiment, the first power semiconductor is an SiC-MOSFET, and a second power semiconductor is an Si-IGBT.

In one embodiment, the dead time and modulation frequency are determined in the parameter selector on the basis of a predefined truth table.

In one embodiment, the control signal is determined in the unit for generating a control matrix on the basis of the predefined truth table.

In one embodiment, there is a gate driver for each output and each topological switch. In another embodiment, there is only one gate driver for numerous topological switches, to which all control signals are output.

An electronic module for controlling an electric drive in a vehicle is also proposed, which contains an inverter with the signal output component referred to above. An electric drive for a vehicle that contains the electronic module and a vehicle with an electric drive are also proposed.

A method is also proposed for controlling at least one gate driver on the basis of the states of at least two power semiconductors, which form a topological switch and are made of different semiconductor materials and/or types, by means of a signal output component, which has an output for each power semiconductor. Control takes place with a first input signal, and a state variable or state variable vector that forms a second input signal, which are converted to a computing value and logical value indicating which of the power semiconductors are to be activated. The dead time and modulation frequency parameters needed for controlling the gate driver are also determined from the logical value, in which a degree of modulation is determined from the first input signal and the computing value, and the logical value, dead time, and modulation frequency are linked to one another, from which at least one control signal is determined that is output to the at least one gate driver.

Other features and advantages of the invention can be derived from the following description of exemplary embodiments of the invention, the drawing showing details of the invention, and the claims. The individual features can be implemented in and of themselves or combined arbitrarily to obtain different variants of the invention.

Preferred embodiments of the invention shall be explained in greater detail below in reference to the drawing.

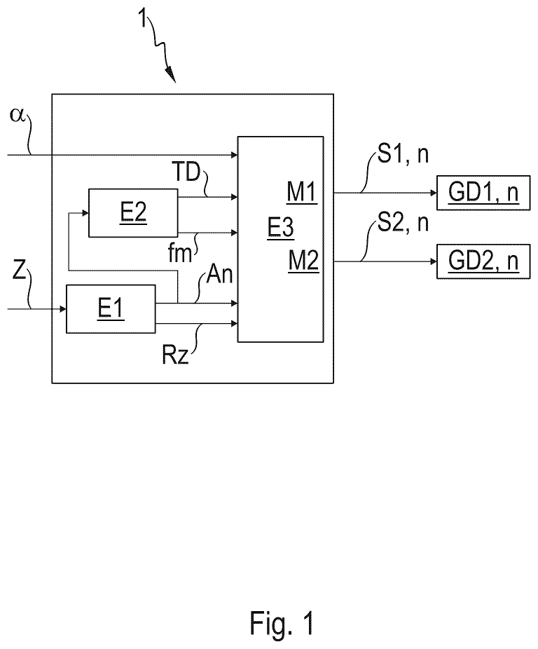

FIG. 1 shows a circuit assembly for the signal output component 1 according to one embodiment of the present invention.

Inverters, also referred to as converters, require a power module or semiconductor package for converting direct current from a battery to alternating current. The power module contains topological switches with semiconductor transistors forming power transistors (also referred to as power semiconductors), which are used to control the current and generate the alternating current. There are numerous types of power transistors for this. These include MOSFETs (metal-oxide-semiconductor field-effect transistors) and IGBTs (insulated-gate bipolar transistors).

The semiconductor material can be silicon (Si), silicon carbide (SiC), gallium nitride (GaN) or any other appropriate semiconductor material.

In order to achieve stricter fleet efficiency goals (from lawmakers) in the field of electric mobility, it is necessary to increase the efficiency of the inverters through the use of novel semiconductor technologies, e.g. SiC-MOSFFETs. The semiconductor surface area for a normal, i.e. average, driving mode is oversized for this, because the design-relevant operating point is rarely obtained. The problem with this is that the semiconductors used in novel technologies (wideband gap semiconductors: WBG semiconductors), which are inherently more efficient (e.g. SiC or GaN), are more expensive than conventional silicon. With conventional systems that have semiconductors made of a less expensive material (e.g. silicon), they can be large enough to provide a safety margin with regard to the design-relevant operating point, because they are not as expensive as WBG semiconductors of the same size. When WBG semiconductors are used in a conventional design, they not only use up more space, they are also more expensive. It is therefore necessary to find an optimal balance between technological advantages and costs.

For this, the types of semiconductors and the semiconductor materials that are to be used in the power semiconductors (also referred to simply as semiconductors), are selected for their specific applications, i.e. their intended uses.

Complementary high-side and low-side switches are used to obtain half bridges. To prevent short circuiting, one switch must be switched off before the complementary switch can be switched on. It is absolutely necessary to wait until the first switch is completely off. The complementary switch must remain off during this period. This period is referred to as dead time (TD), and is usually ca. 2-5 times as long as the switching process. Using an SiC semiconductor, it is possible to switch at a faster rate. This results in a higher modulation frequency fm.

Control patterns can differ with regard to dead times and modulation frequency. An SiC-MOSFET can be switched with shorter dead times TD and higher modulation frequencies fm than an Si-IGBT. Although an output designed for an SiC-MOSFET can also be operated with an Si-IGBT control pattern, the reverse is not possible.

Moreover, the control signals for gate-drivers GD are usually generated with microcontrollers that form signal output components 1. The inputs for signal generation are, e.g.:
a rotor position sensor signal α, which indicates a rotational angle between the stator and the rotor in an electric machine,
a current sensor signal, with which a regulator determines the modulation necessary to obtain the target output current,
a dead time TD for a specific semiconductor type and/or material,
a maximum modulation frequency fm for a specific semiconductor type and/or material.

The output value in this case is a control signal M, which is sent to a gate driver GD. The control signal Mn can be a pulse-width modulated signal, which has been modulated on the basis of the input values (the frequency of the PWM signal corresponds to the frequency modulation). Furthermore, m and a, which depict a momentary value for an inverter output current, are plotted in the duty cycle for the PWM. It should be noted here that a gate driver GD can only control one topological switch. This means that six gate drivers GD are needed to control a B6 bridge, requiring the generation of six phase-offset control signals Mn.

Prior signal output components 1 (i.e. microcontrollers) for gate drivers GD could not output control signals Mn for specific semiconductor types and/or materials to gate drivers GD1.n, GD2.n with which different semiconductor types and materials were to be controlled. Global control patterns for numerous outputs are less than optimal, because they make inefficient use of the various semiconductor types and/or materials.

For this reason, a signal output component 1 is proposed that can output control signals Mn for different semiconductor types and/or materials to one or more gate drivers GD, which can then control power semiconductors made of different semiconductor materials and/or different semiconductor types connected in parallel. One embodiment thereof is shown in FIG. 1, which shall be explained below.

The signal output component 1 has the advantage that it has numerous outputs S1.n; S2.n, which can be controlled using different control patterns, or control signals Mn. Each of the outputs S1.n, S2.n has a dedicated gate driver GD1.n, GD2.n with which they are controlled by the control patterns or signals M1, M2 determined in the signal output component 1. This also has the advantage that as a result of being able to generate different control signals M1, M2 for numerous gate drivers GD1.n, GD2.n in a single signal output component 1, which is normally a microcontroller, the number of signal generating blocks can be reduced (from the previous one for each gate driver GD1.n, GD2.n).

A signal output component 1 with two inputs, to which two signals a and Z are provided, and two outputs S1.n and S2.n, is shown in FIG. 1. Each of the outputs S1.n, S2.n are used to control a gate driver GD1.n, GD2.n, which in turn can control a power semiconductor. As mentioned numerous times above, the power semiconductors can be made of different semiconductor materials and/or types, thus requiring separate control thereof. The power semiconductors always form topological switches with a high-side switch and low-side switch.

An input in the signal output component 1 receives the rotor position sensor signal α, as in the prior art. This is sent directly to the unit for generating a control matrix E3, which shall be described below.

A state vector Z or state variable is sent to the other input, which is then sent to a converter E1. The state vector Z is advantageous if numerous physical variables are used to describe the state.

State variables of the state variables or state vectors Z contain control data for the power semiconductors, i.e. at least the data relating to the dead time TD and control frequency or modulation frequency fm, as well as physical values that can be used for controlling the power semiconductors, i.e. values for controlling, regulating, and/or monitoring power electronics. This type of variable can be the aforementioned current sensor signal, the current, the effective value for the current, or the temperature, all of which can also be further subdivided. By way of example, the intake or discharge temperatures of cooling water, and/or semiconductor temperatures can be used. Moreover, phase currents or battery currents, the charging state of the battery, voltages in the intermediate circuit, position of the gas pedal, and therefore the current performance requirements, can be used as state variables or state vectors, if numerous variables are to be taken into consideration.

The state values or variables, or the state vectors Z can be detected at both the input side of the semiconductor switch, e.g. cooling water temperatures, and the output side of the semiconductor switch, e.g. the temperature of the power semiconductor.

A computing value constant Rz is obtained from the state variables or state vectors Z in the converter E1, which is sent directly to the unit for generating a control matrix E3 described below. A fixed relationship to the degree of modulation m is obtained from the computing value Rz in which m=x*Rz. With space vector modulation, x can be less than or equal to 1.15. The maximum m is characteristic value for the application, and forms the requirement for the maximum output amperage ab that the inverter can provide.

A logical value An is also obtained from the state variable or state vector Z in the converter E1, which indicates which power semiconductor and therefore which gate driver GD1.n, GD2.n is to be controlled, and which is advantageously provided as a computing value vector containing as many elements are there are outputs. The logical value An is sent to the unit for generating a control matrix E3 and a parameter selector E2.

The logical value An forming the computing value or computing value vector can contain 2n logic level patterns. This means that if the topological switch is made of two (n=2) semiconductor types and/or materials, four different patterns can be output (22=4), which can be defined based on different logic levels. These levels can correspond to different ranges of a required performance output. A reference table can be created on the basis of the required performance output, indicating which power semiconductor is to be used. A computer, e.g. a control unit intended for executing the method, can output this.

The dead time TD and modulation frequency fm needed to control the gate drivers GD1.n, GD2.n are determined from the logical value An in the parameter selector E2. This means that this is where it is decided which dead time TD, which frequency modulation fm, and which modulation method are to be used to modulate the output signal. This block therefore determines whether the gate driver 1 is to control a semiconductor with a long dead time TD and low modulation frequency fm, or with a short dead time TD and high modulation frequency fm.

The functioning corresponds to the following truth table (1):

| | | |
|---|---|---|
| An | TD | fm |

| | | | |
|---|---|---|---|
| 0 | 0 | 0 | 0 |
| 0 | 1 | TD1 | fm1 |
| 1 | 0 | TD2 | fm2 |
| 1 | 1 | TD2 | fm2 |

The results are sent to the unit for generating a control matrix E3. The computing value An and selected parameters TD and fm are linked there, as shown in the following truth table (2):

| | | | | |
|---|---|---|---|---|
| An | TD | fm | S_{2.n} | S_{1.n} |

| | | | | | |
|---|---|---|---|---|---|
| 0 | 0 | 0 | 0 | 0 | 0 |
| 0 | 1 | TD1 | fm1 | 0 | M1 |
| 1 | 0 | TD2 | fm2 | M2 | 0 |
| 1 | 1 | TD2 | fm2 | M2 | M2 |

This shows that the output S2.n can only be operated with the output pattern vector M2, and the output S1.n can be operated with both M1 and M2.

The function block is also sent the rotor position signal a and the computing value Rz in order to calculate the necessary degree of modulation.

The final control signal Mn is obtained from these input values, which is then sent to the gate drives GD1.n, GD2.n through the outputs S1.n, S2.n.

Output S1.n is designed to control a gate driver 1 with a short TD.1 and a high fm.1. The second output S2.n is designed to control a gate driver with a TD.2≥TD.1 and an fm.2≤fm.1. Other outputs Sn+1 can be configured for TD.n+1≥TD.n, and fm.n+1≤fm.n. This results in the possibility that the output S1.n does not automatically have to be controlled with TD.1 and fm.1, but can also be controlled with control patterns that have longer dead times TD and lower modulation frequencies fm.

This also makes it possible to operate numerous outputs in parallel with the same control patterns, as long as the longer dead times TD and lower modulation frequencies fm are obtained in the control patterns.

By way of example, if two different power semiconductors are used, one is an SiC-MOSFET with a dead time TD.1 of 500 ns, and modulation frequency fm.1 of 20 KHz. The other is then an Si-IGBT with a dead time TD.2 of 2.5 us and a modulation frequency fm.2 of 10 KHz. This results in two input pattern vectors, of which the one with the parameters TD.1 and fm.1 is intended for controlling the gate driver GD1.n and the other is intended for controlling the gate drive GD2.n, which are then output at the corresponding outputs S1.n or S2.n.

One gate drive GD can be used for each output S1.n, S2.n and each topological switch with the invention. Advantageously, a conventional gate driver GD can be used for this.

Alternatively, a single gate drive GD can be used, which can control numerous power semiconductors made of different semiconductor materials and/or types. Advantageously, both output signals can be transmitted with a physical signal line, thus ensuring that the “right” control signal for the power semiconductor in question is selected.

The control method can be obtained with software, hardware, or a combination thereof. The advantage of the proposed signal output component 1 and the control method is in the possibility of controlling different power semiconductors made of different semiconductor materials and/or types in the microcontroller instead of in the gate driver GD. The proposed method can be used with inverter in the field of electric mobility, i.e. to control an electric drive or some other electric machine.

### LIST OF REFERENCE SYMBOLS

1 signal output component
GD1.n, GD2.n gate drivers
TD dead time
fm frequency modulation
An logical value
Rz computing value
α rotor position signal
E1 converter
E2 parameter selector
E3 unit for generating a control matrix
M1, M2 control signal
S1.n, S2.n outputs
Z state vector

1. A signal output component for controlling at least one gate driver for controlling at least two power semiconductors that form a topological switch and are made of different semiconductor materials and/or semiconductor types, wherein the signal output component comprises:
an output for each power semiconductor;
a unit for generating a control matrix, which outputs at least one output signal to at least one output;
a first input, from which a predefined input signal is sent directly to the unit for generating a control matrix;
a second input, from which a state variable or state variable vector is sent to a converter, in which the state variable or state variable vector is converted to a computing value and a logical value indicating which of the power semiconductors is to be used, which computing value and logical value are sent directly to the unit for generating a control matrix; and
a parameter selector to which the logical value is sent, from which a dead time and modulation frequency parameters needed to control the gate driver are calculated and sent to the unit for generating a control matrix,
wherein a degree of modulation is calculated in the unit for generating a control matrix from the input signal and the computing value, and the logical value, dead time and modulation frequency are linked to one another, and at least one control signal is determined therefrom, which is sent through the outputs to the at least one gate driver.

2. The signal output component according to claim 1,
wherein the first output is configured to control a first power semiconductor of the at least two power semiconductors with a first dead time and a first modulation frequency, and
wherein every other output is configured to control every other power semiconductor of the at least two power semiconductors with another dead time and another modulation frequency,
wherein: T_{D,n+1}≥T_{D,1} and fm.n+1≤fm.n, where n is a number of outputs.

3. The signal output component according to claim 1, wherein a first power semiconductor of the at least two power semiconductors is an SiC-MOSFET, and a second power semiconductor of the at least two power semiconductors is an Si-IGBT.

4. The signal output component according to claim 1, wherein the dead time and modulation frequency are determined in the parameter selector using a predefined truth table.

5. The signal output component according to claim 1, wherein the control signals are determine in the unit for generating a control matrix using a predefined truth table.

6. The signal output component according to claim 1, wherein there is a gate driver for each output and each topological switch.

7. The signal output component according to claim 1, wherein there is a single gate driver for controlling the at least two power semiconductors, which form a topological switch and are made of different semiconductor materials and/or semiconductor types, to which all control signals are output.

8. An electronic module for controlling an electric drive in a vehicle, wherein the electronic module comprises an inverter comprising:
the signal output component according to claim 1.

9. An electric drive for a vehicle, comprising:
the electronic module according to claim 8.

10. A vehicle comprising:
the electric drive according to claim 9.

11. A method for state-based control of at least one gate driver for controlling at least two power semiconductors that form a topological switch and are made of different semiconductor materials and/or semiconductor types, with a signal output component, which has one output for each power semiconductor, the method comprising:
obtaining a predefined first input signal;
obtaining a state variable or state variable vector that forms a second input signal, wherein the state variable or state variable vector is converted into a computing value and a logical value, indicating which power semiconductor is to be used; and
determining dead time and modulation frequency parameters needed to control the gate driver from the logical value, wherein
a degree of modulation is calculated from the first input signal and the computing value, and the logical value, dead time and modulation frequency are linked to one another, from which at least one control signal is determined, which is sent through the outputs to the at least one gate driver.

12. The method according to claim 11, comprising:
controlling, by a first output, a first power semiconductor of the at least two power semiconductors with a first dead time and a first modulation frequency; and
controlling every other output to control every other power semiconductor of the at least two power semiconductors with another dead time and another modulation frequency,
wherein: T_{D,n+1}≥T_{D,1} and fm.n+1≤fm.n, where n is a number of outputs.

13. The method according to claim 11, wherein a first power semiconductor of the at least two power semiconductors is an SiC-MOSFET, and a second power semiconductor of the at least two power semiconductors is an Si-IGBT.

14. The method according to claim 11, comprising:
determining the dead time and modulation frequency using a predefined truth table.

15. The method according to claim 11, comprising:
determining the control signals using a predefined truth table.

16. The method according to claim 11,
wherein there is a gate driver for each output and each topological switch.

17. The method according to claim 11,
wherein there is a single gate driver for controlling the at least two power semiconductors, which form a topological switch and are made of different semiconductor materials and/or semiconductor types, to which all control signals are output.
